(19) United States
(12) Patent Application Publication
(10) Pub. No.: US 2017/0077166 A1
(43) Pub. Date: Mar. 16, 2017

(54) IMAGE SENSOR DEVICE

(71) Applicant: Renesas Electronics Corporation, Tokyo (JP)

(72) Inventors: Tatsuya KITAMORI, Tokyo (JP); Kyoji YAMASAKI, Tokyo (JP); Katsumi EIKYU, Tokyo (JP)

(73) Assignee: Renesas Electronics Corporation, Tokyo (JP)

(21) Appl. No.: 15/218,257

(22) Filed: Jul. 25, 2016

(30) Foreign Application Priority Data
Sep. 14, 2015 (JP) 2015-180391

(51) Int. Cl. H01L 27/146

(52) U.S. Cl. CPC H01L 27/14643; H01L 27/14612; H01L 27/14627; H01L 27/14621

(57) ABSTRACT

Image sensor devices of related art have a problem that an auto-focus accuracy deteriorates due to crosstalk of electrons between a plurality of photodiodes formed below one microlens. According to one embodiment, at least some of a plurality of pixels in an image sensor device include: first and second photoelectric conversion elements (PD_L, PD_R) that are formed on a semiconductor substrate below one microlens (45); and a potential barrier (34) that inhibits transfer of electric charges between at least a part of a lower region of the first photoelectric conversion element (PD_L) and at least a part of a lower region of the second photoelectric conversion element (PD_R) in a depth direction of the semiconductor substrate.

### CROSS-REFERENCE TO RELATED APPLICATIONS

This application is based upon and claims the benefit of priority from Japanese patent application No. 2015-180391, filed on Sep. 14, 2015, the disclosure of which is incorporated herein in its entirety by reference.

### BACKGROUND

The present invention relates to an image sensor device, and more particularly, to an image sensor device having, for example, a phase difference auto-focus function.

In image pickup devices such as a camera, a CCD or CMOS sensor is used as an image sensor device, and an image obtained by the image sensor device is output as photographing data. Many of the image pickup devices have an auto-focus function for automatically enhancing the sharpness of an image to be photographed. A phase difference method is known as a method for implementing the auto-focus function.

In the phase difference method, one or two pairs of light-receiving units are provided for each of microlenses arranged in a two-dimensional array, and the light-receiving units are projected by the microlens onto the pupil of an image pickup optical system, thereby dividing the pupil. In the phase difference method, object images are respectively formed by two light beams passing through different areas of the pupil of the image pickup optical system and the positional phase difference between the two object images is detected based on the output of the image sensor device and is converted into the defocus amount of the image pickup optical system. Japanese Patent No. 3774597 discloses an example of image pickup devices having the auto-focus function using the phase difference method as described above.

### SUMMARY

However, in the image pickup devices including a first photoelectric conversion unit (for example, a photodiode) and a second photodiode, such as the image pickup device disclosed in Japanese Patent No. 3774597, the crosstalk of electrons between the two photodiodes occurs. The occurrence of crosstalk of electrons between the photodiodes causes deterioration of the auto-focus accuracy. Other problems to be solved by and novel features of the present invention will become apparent from the following description and the accompanying drawings.

According to one embodiment, at least some of a plurality of pixels of an image sensor device include: a first photoelectric conversion element and a second photoelectric conversion element that are formed on a semiconductor substrate, the first photoelectric conversion element and the second photoelectric conversion element being formed below one microlens; and a potential barrier that inhibits transfer of electric charges between at least a part of a lower region of the first photoelectric conversion element and at least a part of a lower region of the second photoelectric conversion element in a depth direction of the semiconductor substrate.

According to the one embodiment, it is possible to provide an image sensor device capable of implementing an auto-focus function for controlling a focus with a high accuracy.

### BRIEF DESCRIPTION OF THE DRAWINGS

The above and other aspects, advantages and features will be more apparent from the following description of certain embodiments taken in conjunction with the accompanying drawings, in which:

FIG. 1 is a block diagram showing a camera system including an image sensor device according to a first embodiment;

FIG. 2 is a schematic diagram showing a floor layout of the image sensor device according to the first embodiment;

FIG. 3 is a circuit diagram showing pixel units of the image sensor device according to the first embodiment;

FIG. 4 is a schematic diagram showing a layout of a pixel unit of the image sensor device according to the first embodiment;

FIG. 5 is a sectional view showing a photoelectric conversion element region of the image sensor device according to the first embodiment;

FIG. 6 is a diagram for explaining a method for manufacturing the photoelectric conversion element region of the image sensor device according to the first embodiment;

FIG. 7 shows graphs for explaining impurity implantation parameters in a manufacturing process;

FIG. 8 is a diagram for explaining the principle of phase difference auto-focus in the image sensor device according to the first embodiment;

FIG. 9 is a graph for explaining outputs of photoelectric conversion elements when defocus occurs in the image sensor device according to the first embodiment;

FIG. 10 is a timing diagram showing an operation of the image sensor device during auto-focus control according to the first embodiment;

FIG. 11 is a diagram for explaining a potential within the photoelectric conversion element region of the image sensor device according to the first embodiment;

FIG. 12 is a diagram for explaining a potential within a photoelectric conversion element region of an image sensor device according to a comparative example;

FIG. 13 is a diagram for explaining a difference in the location where electrons are generated due to a difference between incident light wavelengths in the photoelectric conversion element region of the image sensor device according to the first embodiment;

FIG. 14 is a diagram for explaining a difference between locations where electrons are generated due to a difference between incident light wavelengths in the photoelectric conversion element region of the image sensor device according to the comparative example;

FIG. 15 shows graphs for explaining input/output characteristics of the photoelectric conversion element region of the image sensor device according to the first embodiment;

FIG. 16 shows graphs for explaining input/output characteristics of the photoelectric conversion element region of the image sensor device according to the comparative example;

FIG. 17 is a diagram for explaining a potential within a photoelectric conversion element region of an image sensor device according to a second embodiment;

FIG. 18 is a diagram for explaining a potential within a photoelectric conversion element region of an image sensor device according to a third embodiment;

FIG. 19 is a graph for explaining input/output characteristics of the photoelectric conversion element region of the image sensor device according to the third embodiment.

### DETAILED DESCRIPTION

### First Embodiment

The following description and the drawings are abbreviated or simplified as appropriate for clarity of explanation. The elements illustrated in the drawings as functional blocks for performing various processes can be implemented hardwarewise by a CPU, a memory, and other circuits, and softwarewise by a program loaded into a memory. Accordingly, it is understood by those skilled in the art that these functional blocks can be implemented in various forms including, but not limited to, hardware alone, software alone, and a combination of hardware and software. Note that in the drawings, the same elements are denoted by the same reference numerals, and repeated descriptions thereof are omitted as needed.

The above-mentioned program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g., magneto-optical disks), CD-ROM (Read Only Memory), CD-R, CD-R/W, and semiconductor memories (such as mask ROM, PROM (Programmable ROM), EPROM (Erasable PROM), flash ROM, RAM (Random Access Memory), etc.). The program may be provided to a computer using any type of transitory computer readable media. Examples of transitory computer readable media include electric signals, optical signals, and electromagnetic waves. Transitory computer readable media can provide the program to a computer via a wired communication line, such as electric wires and optical fibers, or a wireless communication line.

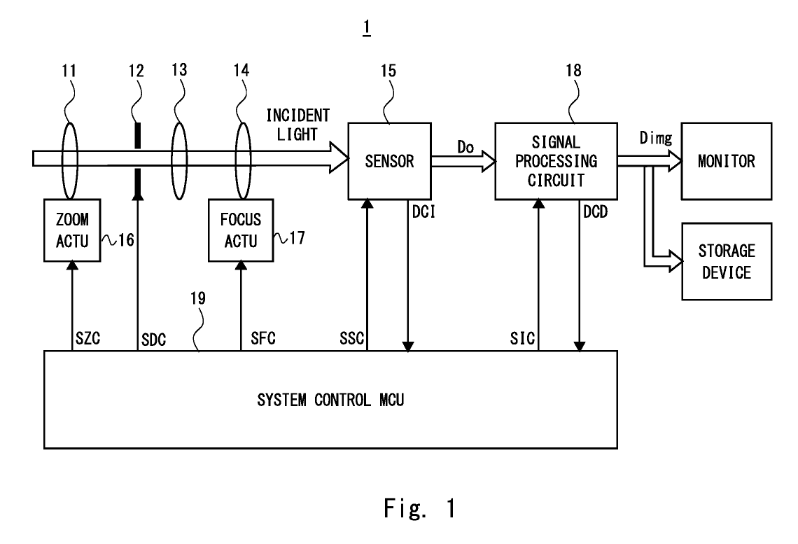

FIG. 1 shows a block diagram of a camera system 1 according to a first embodiment. As shown in FIG. 1, the camera system 1 includes a zoom lens 11, an aperture mechanism 12, a fixed lens 13, a focus lens 14, a sensor 15, a zoom lens actuator 16, a focus lens actuator 17, a signal processing circuit 18, a system control MCU 19, a monitor, and a storage device. In this case, the monitor and the storage device are used to check and store images photographed by the camera system 1. The monitor and the storage device may be provided on another system separately from the camera system 1.

The zoom lens 11, the aperture mechanism 12, the fixed lens 13, and the focus lens 14 constitute a lens group of the camera system 1. The position of the zoom lens 11 is changed by the zoom actuator 16. The position of the focus lens 14 is changed by the focus actuator 17. In the camera system 1, the lenses are moved by various actuators to thereby change the zoom magnification and focus, and the aperture mechanism 12 is operated to thereby change the amount of incident light.

The zoom actuator 16 causes the zoom lens 11 to move based on a zoom control signal SZC output from the system control MCU 19. The focus actuator 17 causes the focus lens 14 to move based on a focus control signal SFC output from the system control MCU 19. The aperture mechanism 12 adjusts an aperture amount according to an aperture control signal SDC output from the system control MCU 19.

The sensor 15 corresponds to an image sensor device according to the first embodiment. The sensor 15 includes a photoelectric conversion element, such as a photodiode. The sensor 15 converts light-receiving pixel information received from the light-receiving element into a digital value, and outputs image information Do. Further, the sensor 15 analyzes the image information Do output from the sensor 15, and outputs image characteristic information DCI representing the characteristics of the image information Do. The image characteristic information DCI includes two images obtained in auto-focus processing to be described later. Furthermore, the sensor 15 performs a gain control for each pixel of the image information Do, an exposure control for the image information Do, and an HDR (High Dynamic Range) control for the image information Do, based on a sensor control signal SSC received from the system control MCU 19. The details of the sensor 15 will be described later.

The signal processing circuit 18 performs image processing, such as image correction, on the image information Do received from the sensor 15, and outputs image data Dimg. The signal processing circuit 18 analyzes the received image information Do and outputs color space information DCD. The color space information DCD includes, for example, brightness information and color information of the image information Do.

The system control MCU 19 controls the focus of the lens group based on the image characteristic information DCI output from the sensor 15. Specifically, the system control MCU 19 outputs the focus control signal SFC to the focus actuator 17, to thereby control the focus of the lens group. The system control MCU 19 outputs the aperture control signal SDC to the aperture mechanism 12, to thereby adjust the aperture amount of the aperture mechanism 12. Further, the system control MCU 19 generates the zoom control signal SZC according to a zoom instruction received from the outside, and outputs the zoom control signal SZC to the zoom actuator 16 to thereby control the zoom magnification of the lens group.

More specifically, defocus occurs when the zoom lens 11 is moved by the zoom actuator 16. Accordingly, the system control MCU 19 calculates a positional phase difference between two object images based on the two images included in the image characteristic information DCI obtained from the sensor 15, and calculates the defocus amount of the lens group based on the positional phase difference. The system control MCU 19 controls an image surface to be automatically focused according to the defocus amount. This processing is referred to as auto-focus control.

Further, the system control MCU 19 controls the exposure setting and gain setting for the sensor 15 in such a manner that an exposure control value to instruct the exposure setting for the sensor 15 is calculated based on the brightness information included in the color space information DCD output from the signal processing circuit 18 and the brightness information included in the color space information DCD output from the signal processing circuit 18 indicates a value closer to the exposure control value. At this time, the system control MCU 19 may calculate a control value for the aperture mechanism 12 when the exposure is changed.

Furthermore, the system control MCU 19 outputs a color space control signal SIC to adjust the brightness or color of the image data Dimg based on an instruction from a user. The system control MCU 19 generates the color space control signal SIC based on the difference between the color space information DCD obtained from the signal processing circuit 18 and the information supplied from the user.

One of the features of the camera system 1 according to the first embodiment is the control method for the sensor 15 when the sensor 15 obtains the image information Do in the auto-focus processing. The sensor 15 will be described in more detail below.

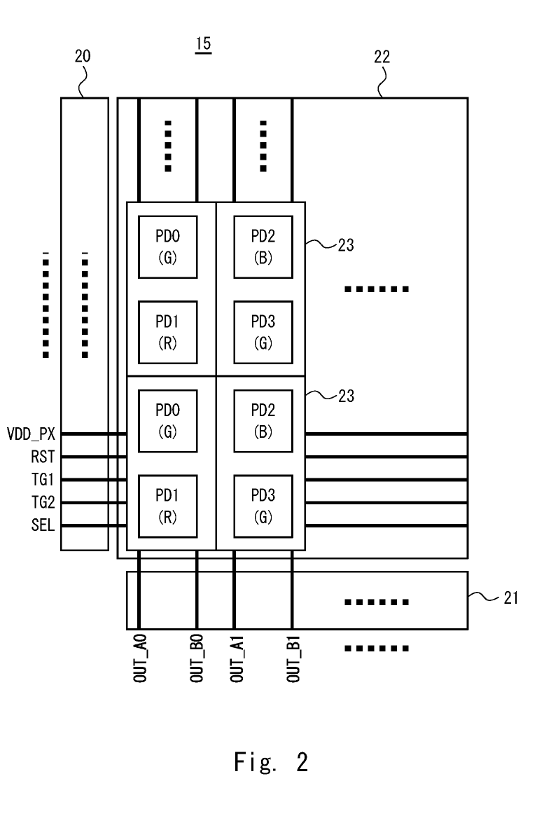

FIG. 2 is a schematic diagram showing a part of the floor layout of the image sensor device according to the first embodiment. FIG. 2 illustrates only the floor layout of a row controller 20, a column controller 21, and a pixel array 22 in the floor layout of the sensor 15.

The row controller 20 controls the active state of each of pixel units 23, which are arranged in a lattice form, in each row. The column controller 21 reads out, in each column, a pixel signal read out from each of the pixel units 23 arranged in a lattice form. The column controller 21 includes a switch circuit and an output buffer to read out the pixel signal. The pixel array 22 includes the pixel units 23 which are arranged in a lattice form. In the example shown in FIG. 2, each pixel unit 23 includes a photodiode group composed of at least one photoelectric conversion element (for example, a photodiode PD) in the row direction. Specifically, each pixel unit 23 is composed of two photodiodes (for example, photodiodes PD0 and PD1 or photodiodes PD2 and PD3). The photodiodes are each provided with a color filter. In the example shown in FIG. 2, a Bayer color filter array is employed. In the Bayer method, green (G) color filters which greatly contribute to a brightness signal are arranged in a checkered pattern, and red (R) and blue (B) color filters are arranged in a checkered pattern in the remaining portion. From another perspective, it can be said that the color filters are arranged in such a manner that the pixels adjacent to each other in the vertical and horizontal directions among the plurality of pixels transmit different colors. The pixel array 22 operates in units of pixel units described above. Accordingly, the configuration and operation of each pixel unit will be described below.

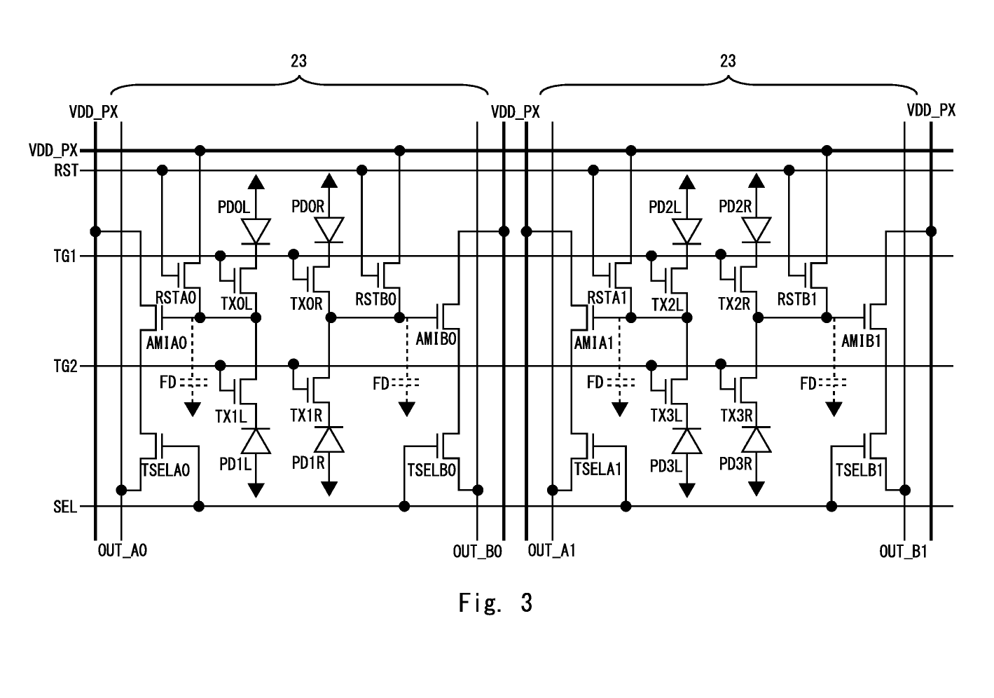

FIG. 3 shows a circuit diagram of each pixel unit 23 of the image sensor device according the first embodiment. The example shown in FIG. 3 illustrates the pixel unit 23 including the photodiodes PD0 and PD1 and the pixel unit 23 including the photodiodes PD2 and PD3. The two pixel units 23 are basically the same except for output lines. Accordingly, only the pixel unit 23 including the photodiodes PD0 and PD1 will be described.

As shown in FIG. 3, in the pixel unit 23, a first photoelectric conversion element (for example, a photodiode PD0L) and a second photoelectric conversion element (for example, a photodiode PD0R) constitute one light-receiving element corresponding to a green color filter. Specifically, as described later, the photodiode PD0L and the photodiode PD0R receive light incident through a microlens which is provided in common to the photodiode PD0L and the photodiode PD0R. The photodiode PD0L and the photodiode PD0R are provided at locations adjacent to each other.

In the pixel unit 23, a third photoelectric conversion element (for example, a photodiode PD1L) and a fourth photoelectric conversion element (for example, a photodiode PD1R) constitute one light-receiving element corresponding to a red color filter. The photodiode PD1L and the photodiode PD1R receive light incident through a microlens which is provided in common to the photodiode PD1L and the photodiode PD1R. The photodiode PD1L and the photodiode PD1R are provided at locations adjacent to each other.

In the pixel unit 23, the photodiode PD0L is provided with a first transfer transistor (for example, a transfer transistor TX0L), and the photodiode PD0R is provided with a second transfer transistor (for example, a transfer transistor TX0R). The gates of the transfer transistor TX0L and the transfer transistor TX0R are connected to a first readout timing signal line TG1 for supplying a first readout timing signal which is commonly used for the transfer transistors. In the pixel unit 23, the photodiode PD1L is provided with a third transfer transistor (for example, a transfer transistor TX1L), and the photodiode PD1R is provided with a fourth transfer transistor (for example, a transfer transistor TX1R). The gates of the transfer transistor TX1L and the transfer transistor TX1R are connected to a second readout timing signal line TG2 for supplying a second readout timing signal which is commonly used for the transfer transistors. The second readout timing signal is enabled at a timing different from that of the first readout timing signal.

The drains of the transfer transistors TX0L and TX1L serve as a floating diffusion FD. The drains of the transfer transistor TX0L and the transfer transistor TX1L are connected to the gate of a first amplification transistor (for example, an amplification transistor AMIA0). The drains of the transfer transistor TX0L and the transfer transistor TX1L are connected to the source of a first reset transistor (for example, a reset transistor RSTA0). The drain of the reset transistor RSTA0 is supplied with a power supply voltage via a power supply line VDD_PX. The amplification transistor AMIA0 amplifies a first voltage, which is generated by electric charges output via the transfer transistors TX0L and TX1L, and outputs the amplified first voltage to a first output line OUT_A0. More specifically, the drain of the amplification transistor AMIA0 is connected to the power supply line VDD_PX, and the source of the amplification transistor AMIA0 is connected to the first output line OUT_A0 via a first selection transistor (for example, a selection transistor TSELA0). The first output line OUT_A0 outputs an output signal which is generated based on the electric charges read out via the transfer transistors TX0L and TX1L. The gate of the selection transistor TSELA0 is connected to a selection signal line SEL which supplies a selection signal.

The drains of the transfer transistors TX0R and TX1R serve as the floating diffusion FD. The drains of the transfer transistor TX0R and the transfer transistor TX1R are connected to the gate of a second amplification transistor (for example, an amplification transistor AMIB0). The drains of the transfer transistor TX0R and the transfer transistor TX1R are connected to the source of a second reset transistor (for example, a reset transistor RSTB0). The drain of the reset transistor RSTB0 is supplied with the power supply voltage via the power supply line VDD_PX. The amplification transistor AMIB0 amplifies a second voltage, which is generated by electric charges output via the transfer transistors TX0R and TX1R, and outputs the amplified voltage to a second output line OUT_B0. More specifically, the drain of the amplification transistor AMIB0 is connected to the power supply line VDD_PX, and the source of the amplification transistor AMIB0 is connected to the second output line OUT_B0 via a second selection transistor (for example, a selection transistor TSELB0). The second output line OUT_B0 outputs an output signal which is generated based on the electric charges read out via the transfer transistors TX0R and TX1R. The gate of the selection transistor TSELB0 is connected to the selection signal line SEL that supplies the selection signal.

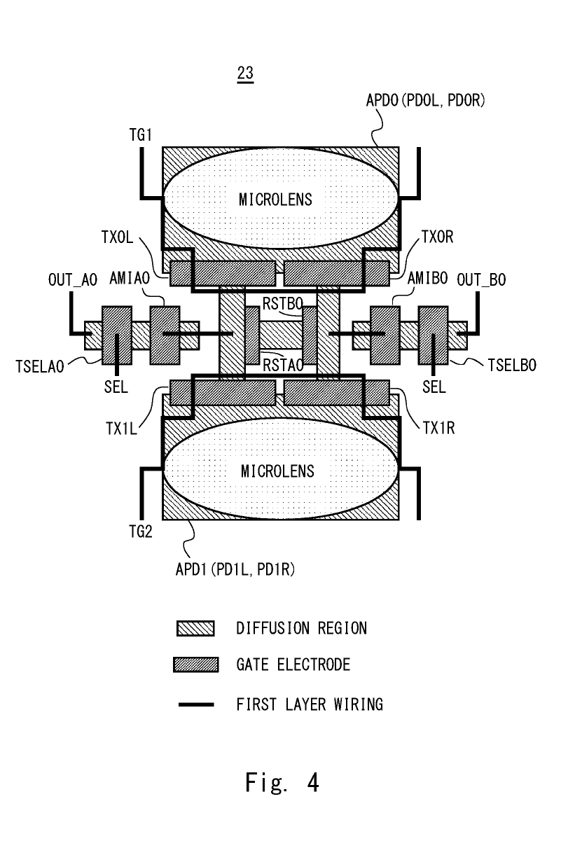

Next, the layout of the pixel unit 23 according to the first embodiment will be described. FIG. 4 is a schematic diagram showing the layout of the pixel unit 23 according to the first embodiment. The layout diagram of FIG. 4 shows only one pixel unit. In FIG. 4, the illustration of the power supply line VDD_PX is omitted.

As shown in FIG. 4, a first photoelectric conversion element region APD0 and a second photoelectric conversion element region APD1 are arranged in the pixel unit 23. In the first photoelectric conversion element region APD0, a first left photoelectric conversion element (for example, the photodiode PD0L) and a first right photoelectric conversion element (for example, the photodiode PD0R) are formed below one microlens. In the second photoelectric conversion element region APD1, a second left photoelectric conversion element (for example, the photodiode PD1L) and a second right photoelectric conversion element (for example, the photodiode PD1R) are formed below one microlens.

The transfer transistor TX0L is formed on a side of the first photoelectric conversion element region APD0 that faces the second photoelectric conversion element region APD1. The gate of the transfer transistor TX0L is connected to the first readout timing signal line TG1. The transfer transistor TX0L is provided so as to correspond to the photodiode PD0L. The transfer transistor TX0R is formed on a side of the first photoelectric conversion element region APD0 that faces the second photoelectric conversion element region APD1. The gate of the transfer transistor TX0R is connected to the first readout timing signal line TG1. The transfer transistor TX0R is provided so as to correspond to the photodiode PD0R. The transfer transistor TX1L is formed on a side of the second photoelectric conversion element region APD1 that faces the first photoelectric conversion element region APD0. The gate of the transfer transistor TX1L is connected to the second readout timing signal line TG2. The transfer transistor TX1L is provided so as to correspond to the photodiode PD1L. The transfer transistor TX1R is formed on a side of the second photoelectric conversion element region APD1 that faces the first photoelectric conversion element region APD0. The gate of the transfer transistor TX1R is connected to the second readout timing signal line TG2. The transfer transistor TX1R is provided so as to correspond to the photodiode PD1R.

In the pixel unit 23, a diffusion region serving as the drain of the transfer transistor TX0L and a diffusion region serving as the drain of the transfer transistor TX1L are formed in one region, and this region is referred to as a first floating diffusion region. In other words, the first floating diffusion region is formed in the region that connects the transfer transistor TX0L and the transfer transistor TX1L to each other. In the pixel unit 23, a diffusion region serving as the drain of the transfer transistor TX0R and a diffusion region serving as the drain of the transfer transistor TX1R are formed in one region, and this region is referred to as a second floating diffusion region. In other words, the second floating diffusion region is formed in the region that connects the transfer transistor TX0R and the transfer transistor TX1R to each other.

In the pixel unit 23, the first reset transistor (for example, the reset transistor RSTA0) is formed so as to be adjacent to the first floating diffusion region, and the second reset transistor (for example, the reset transistor RSTB0) is formed so as to be adjacent to the second floating diffusion region. A diffusion region serving as the source of the reset transistor RSTA0 and a diffusion region serving as the source of the reset transistor RSTB0 are formed in one region.

In the pixel unit 23, the amplification transistor and the selection transistor are formed in the region between the first photoelectric conversion element region APD0 and the second photoelectric conversion element region APD1. More specifically, in the pixel unit 23, the amplification transistor AMIA0 and the selection transistor TSELA0 are formed in the left-side region of the first floating diffusion region shown in FIG. 4. The gate of the amplification transistor AMIA0 is connected to the first floating diffusion region by a line formed of a first layer wiring. The source of the amplification transistor AMIA0 and the drain of the selection transistor TSELA0 are formed in one region. The diffusion region which forms the source of the selection transistor TSELA0 is connected with the first output line OUT_A0. In the pixel unit 23, the amplification transistor AMIB0 and the selection transistor TSELB0 are formed in the right-side region of the second floating diffusion region as shown in FIG. 4. The gate of the amplification transistor AMIB0 is connected to the second floating diffusion region by the line formed of the first layer wiring. The source of the amplification transistor AMIB0 and the drain of the selection transistor TSELB0 are formed in one region. The diffusion region that forms the source of the selection transistor TSELB0 is connected to the second output line OUT_B0.

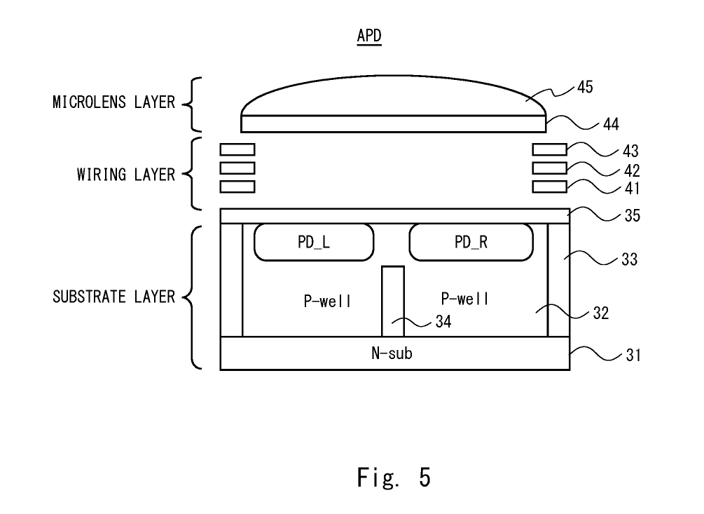

Next, a sectional structure of the photodiode of the pixel unit 23 will be described. The photoelectric conversion element regions included in the pixel unit 23 have the same sectional structure. Accordingly, the sectional structure of one photoelectric conversion element region (hereinafter, the reference symbol “APD” is used to collectively refer to the photoelectric conversion element regions) is herein illustrated, and the structure of each photodiode included in the conversion device region APD is described below. FIG. 5 shows a sectional view of a photodiode portion included in the photoelectric conversion element region APD of the image sensor device according to the first embodiment. In the following description, the reference symbol “PD_L” is used to collectively refer to first and third photodiodes, and the reference symbol “PD_R” is used to collectively refer to second and fourth photodiodes.

As shown in FIG. 5, in the photoelectric conversion element region APD, an N-sub layer 31 is formed on the bottom of a P-well layer 32. A potential wall 33 is formed so as to surround the photoelectric device conversion region APD. The potential wall 33 is formed of, for example, an N-type semiconductor. The photodiodes PD_L and PD_R are formed on the surface of the P-well layer 32 which is surrounded by the potential wall 33. In the P-well layer 32, a potential barrier 34 is formed below the region in which the photodiodes PD_L and PD_R are formed. The potential barrier 34 is formed to inhibit transfer of electric charges (for example, electrons) between at least a part of a lower region of the first diode (for example, the photodiode PD_L) and at least a part of a lower region of the second diode (for example, the photodiode PD_R) in a depth direction of a semiconductor substrate (for example, the P-well layer 32). In the P-well layer 32, a region formed below the region in which the photodiodes PD_L and PD_R are formed serves as an electron accumulation portion. The potential barrier 34 is formed to extend from the bottom of the electron accumulation portion, which is formed below the first photodiode (for example, the photodiode PD_L) and the second photodiode (for example, the photodiode PD_R), in a direction in which the depth of the electron accumulation portion gradually decreases. Further, in the photoelectric conversion element region APD according to the first embodiment, a potential cover 35 is formed so as to cover the photodiodes PD_L and PD_R. The potential cover 35 prevents electrons from flowing into the electron accumulation portion of the photoelectric conversion element region APD from other electron accumulation portions or other regions.

A wiring layer in which lines 41 to 43 are formed is formed above the substrate layer which is composed of the N-sub layer 31 and the P-well layer 32. The microlens in the pixel unit 23 is formed above the wiring layer. In a microlens layer in which the microlens is formed, a microlens 37 is formed above a color filter 36. As shown in FIG. 5, in the pixel unit 23, the microlens 37 is formed so as to cover the pair of photodiodes.

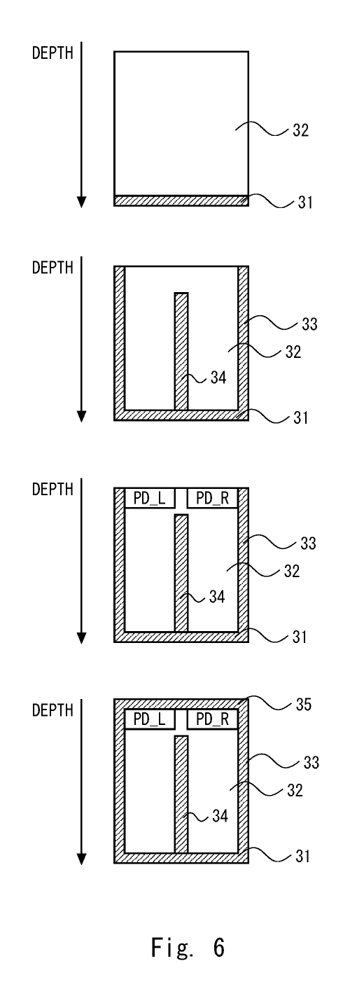

Next, a method for manufacturing the photoelectric conversion element region APD of the image sensor device according to the first embodiment will be described. FIG. 6 is a diagram for explaining the method for manufacturing the photoelectric conversion element region APD of the image sensor device according to the first embodiment. As shown in FIG. 6, in the case of forming the photoelectric conversion element region APD according to the first embodiment, the N-sub layer 31 is first formed on the bottom of the P-well layer 32. The N-sub layer 31 is formed by implanting an N-type impurity, such as boron or phosphorus, into the P-well layer 32. Next, the potential wall 33 is formed in such a manner that the potential wall 33 is continuous with the P-well layer 32 and surrounds the photoelectric conversion element region APD. The potential barrier 34 is formed at the same time when the potential wall 33 is formed. The potential barrier 34 is formed in such a manner that the potential barrier 34 is continuous with the N-sub layer 31 and extends from the deepest position of the P-well layer 32 to the shallowest position thereof. The potential wall 33 and the potential barrier 34 are formed by implanting the N-type impurity into the P-well layer 32.

Next, the photodiodes PD_L and PD_R are formed on the surface of the P-well layer 32 in the region surrounded by the potential wall 33. After that, the potential cover 35 is formed so as to cover the photodiodes PD_L and PD_R. The potential cover 35 is formed of an N-type semiconductor. The potential cover 35 is formed by implanting the N-type impurity into the surface layer of the substrate layer.

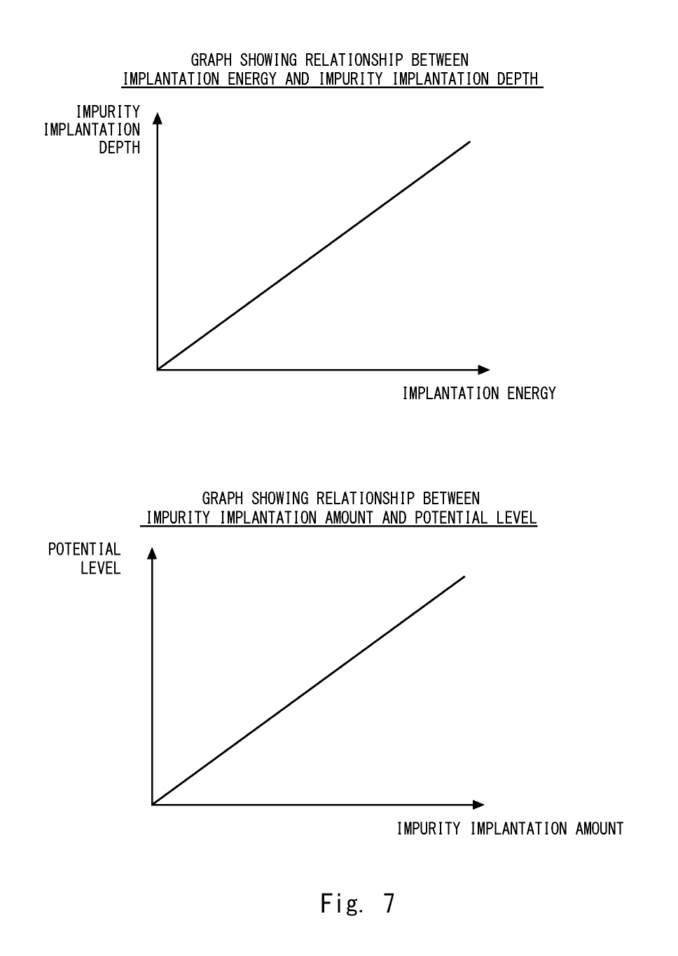

Impurity implantation parameters used in the manufacturing process for the photoelectric conversion element region APD according to the first embodiment will be described. FIG. 7 shows graphs for explaining the impurity implantation parameters used in the manufacturing process. The upper graph of FIG. 7 is a graph showing a relationship between an impurity implantation depth and an implantation energy when impurities are implanted. As shown in the upper graph of FIG. 7, the depth of implantation of an impurity into the P-well layer 32 can be changed by implanting the impurity with a high implantation energy. The potential wall 33 and the potential barrier 34 according to the first embodiment are formed by implanting impurities a plurality of times by changing the implantation energy in a stepwise fashion.

The lower graph of FIG. 7 is a graph showing a relationship between the amount of implanted impurity and the level of the potential in the portion in which the impurity is implanted. As shown in the lower graph of FIG. 7, the level of the potential in the portion in which the impurity is implanted increases as the amount of implanted impurity increases. In the first embodiment, the impurity implantation amount is adjusted in such a manner that at least the potential levels of the potential wall 33, the potential barrier 34, and the N-sub layer 31 are set to be substantially the same.

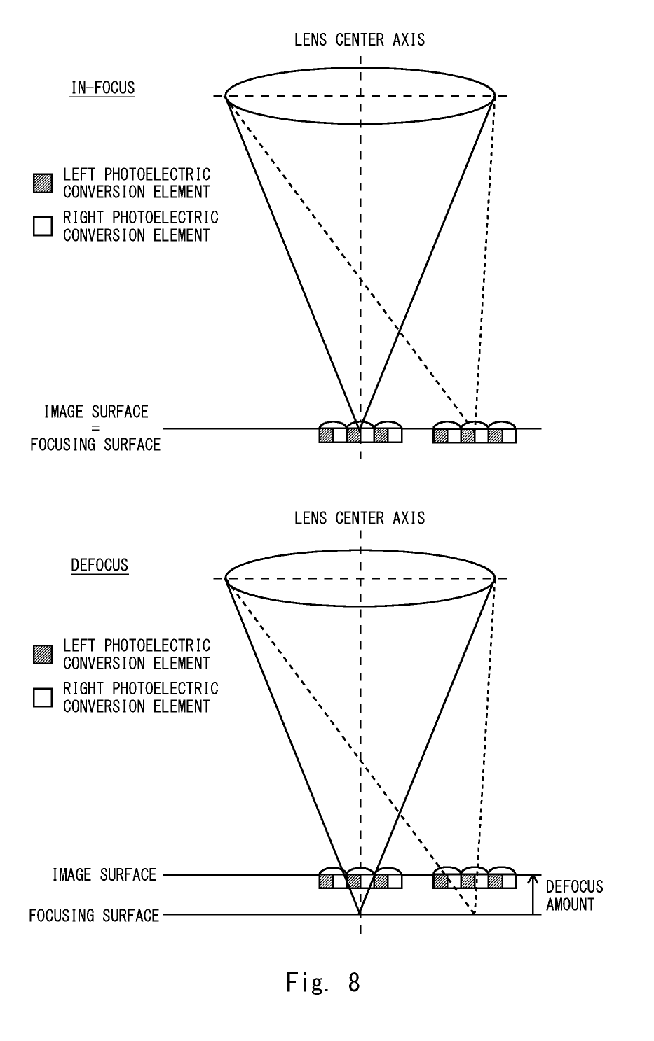

Next, focus of the camera system 1 will be described. FIG. 8 shows a diagram for explaining the principle of phase difference auto-focus in the image sensor device according to the first embodiment. FIG. 8 shows a positional relationship between an evaluation surface (for example, an image surface) formed on the sensor surface and a focusing surface on which an image of light incident from the focus lens is focused.

As shown in FIG. 8, in an in-focus state, the focusing surface on which the image of light incident from the focus lens is focused matches the image surface (see the upper diagram of FIG. 8). On the other hand, in a defocus state, the focusing surface on which the image of light incident from the focus lens is focused is formed at a position different from the position of the image surface (see the lower diagram of FIG. 8). The amount of displacement between the focusing surface and the image surface corresponds to a defocus amount.

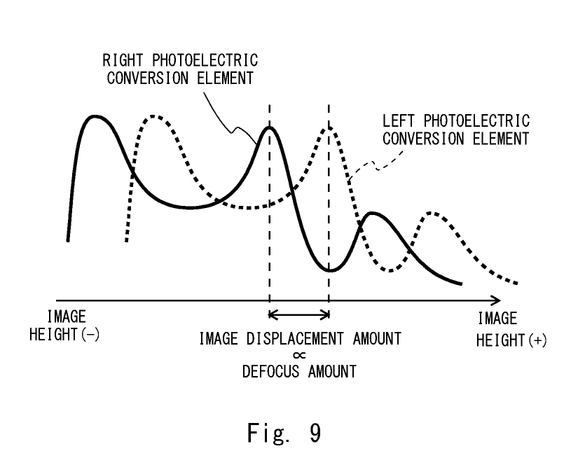

An image to be formed on the image surface when defocus occurs will now be described. FIG. 9 shows a graph for explaining the outputs of the photoelectric conversion elements when defocus occurs. In FIG. 9, the horizontal axis represents an image height indicating a distance from the lens center axis of each photoelectric conversion element, and the vertical axis represents the magnitude of the output of each photoelectric conversion element.

As shown in FIG. 9, when defocus occurs, the signal output from the left photoelectric conversion element and the signal output from the right photoelectric conversion element deviate from each other in the image height direction. The amount of image displacement is a magnitude proportional to the defocus amount. In the camera system 1 according to the first embodiment, the defocus amount is calculated based on the amount of image displacement, and the position of the focus lens 14 is determined.

In the auto-focus processing of the camera system 1 according to the first embodiment, the position of the focus lens 14 is controlled in such a manner that the output signals output from all the pixel units arranged in the pixel array 22 of the sensor 15 are matched between the left photoelectric conversion element and the right photoelectric conversion element. In the camera system 1 according to the first embodiment, the system control MCU 19 controls the position of the focus lens 14 based on resolution information output from the sensor 15.

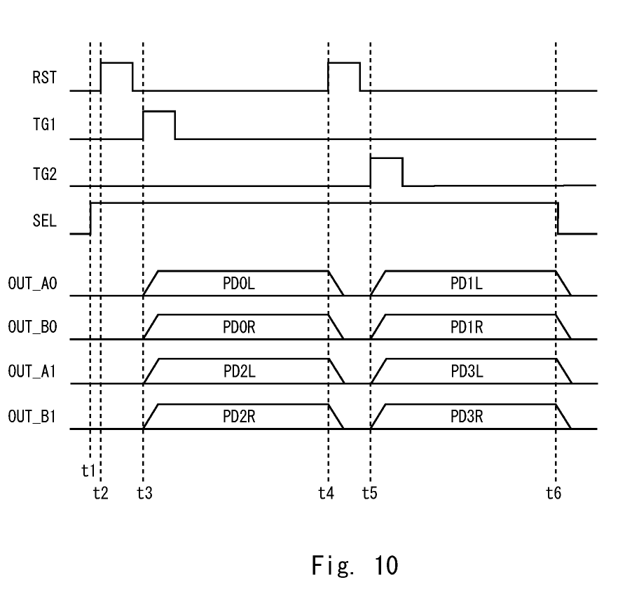

Next, an operation of the sensor 15 during the auto-focus processing according to the first embodiment will be described. FIG. 10 is a timing diagram showing an operation of the image sensor device during the auto-focus control according to the first embodiment. In the illustration of FIG. 10, the reference symbols denoting the respective lines are used to represent the signals transmitted via the respective lines.

As shown in FIG. 10, the sensor 15 switches the selection signal SEL from a low level to a high level at timing t1. This causes the selection transistors TSELA0, TSELB0, TSELA1, and TSELB1 to be rendered conductive. At timing t2, the reset signal RST is switched from the low level to the high level. Accordingly, each floating diffusion FD is reset. Then, after the reset signal is switched to the low level again, the first readout timing signal TG1 is switched to the high level at timing t3. As a result, the output signal based on the electric charges output from the photodiode PD0L is output to the first output line OUT_A0, and the output signal based on the electric charges output from the photodiode PD0R is output to the second output line OUT_B0. Further, the output signal based on the electric charges output from the photodiode PD2L is output to the first output line OUT_A1, and the output signal based on the electric charges output from the photodiode PD2R is output to the second output line OUT_B1.

At timing t4, the reset signal RST is switched from the low level to the high level. Accordingly, each floating diffusion FD is reset. Then, after the reset signal is switched to the low level again, the second readout timing signal TG2 is switched to the high level at timing t5. As a result, the output signal based on the electric charges output from the photodiode PD1L is output to the first output line OUT_A0, and the output signal based on the electric charges output from the photodiode PD1R is output to the second output line OUT_B0. Further, the output signal based on the electric charges output from the photodiode PD3L is output to the first output line OUT_A1, and the output signal based on the electric charges output from the photodiode PD3R is output to the second output line OUT_B1. At timing t6, the selection signal SEL is switched from the high level to the low level.

As described above, in the sensor 15 according to the first embodiment, the outputs from the left photoelectric conversion element and the right photoelectric conversion element, which are provided so as to correspond to one microlens, are carried out by activating one readout timing signal. In other words, in the sensor 15 according to the first embodiment, the outputs from the left photoelectric conversion element and the right photoelectric conversion element, which are provided so as to correspond to one microlens, are carried out at the same timing. Accordingly, in the sensor 15 according to the first embodiment, the accuracy of the auto-focus control can be increased. In this case, when the outputs from two photoelectric conversion elements (for example, photodiodes) are obtained at the same time, crosstalk of electrons between the two photodiodes occurs, which may cause deterioration of the auto-focus accuracy. However, in the sensor 15 according to the first embodiment, the potential barrier 34 is provided in the photoelectric conversion element region APD, thereby preventing the occurrence of crosstalk of electrons between the two photodiodes and increasing the auto-focus accuracy. In this regard, the principle of operation of the photoelectric conversion element region APD of the sensor 15 according to the first embodiment will be described below.

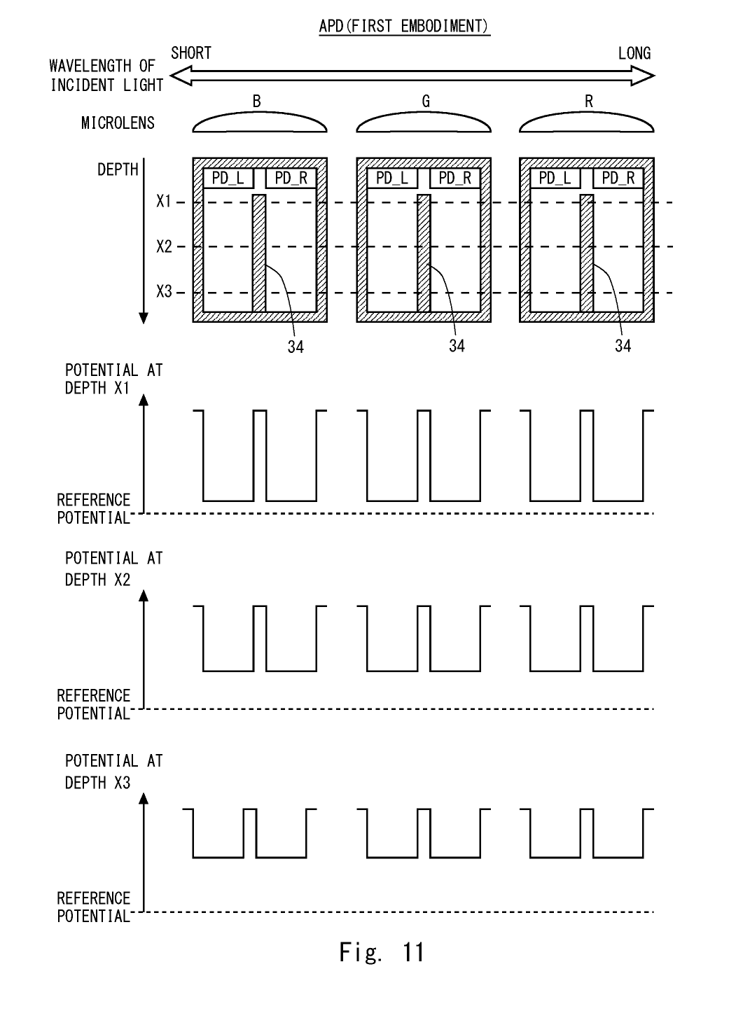

FIG. 11 shows a diagram for explaining a potential within the photoelectric conversion element region ADP of the sensor 15 according to the first embodiment. As shown in FIG. 11, the photoelectric conversion element region ADP of the sensor 15 according to the first embodiment can be divided into photoelectric conversion element regions respectively corresponding to three types of color filters. In the first embodiment, the photoelectric conversion element regions APD respectively corresponding to three types of color filters have the same structure. The wavelength of incident light of blue color (B) is shortest and the wavelength of incident light of red color (R) is longest.

As shown in FIG. 11, the potential of the photoelectric conversion element region APD according to the first embodiment is set in such a manner that the portion below the photodiode PD_L and the portion below the photodiode PD_R have a low potential and the portion corresponding to the potential barrier 34, which is formed so as to separate the two photodiodes from each other, has a high potential. Further, in the photoelectric conversion element region APD according to the first embodiment, the potential of the electron accumulation portion is set in such a manner that the potential gradually decreases in a direction from the photodiodes to the bottom of the photoelectric conversion element region APD. In the photoelectric conversion element region APD, electric charges are collected into the photodiodes by a slope of the potential within the electron accumulation portion.

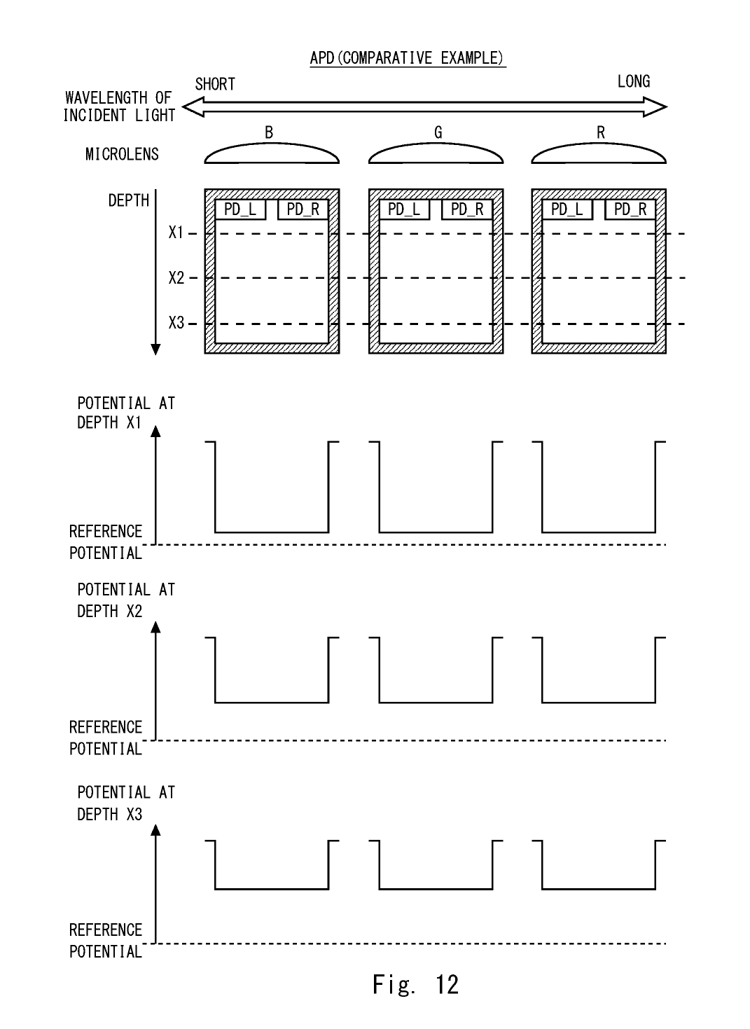

As a comparative example, the photoelectric conversion element region APD which does not include the potential barrier 34 will be described. The principle of operation of the photoelectric conversion element region APD according to the first embodiment will be described in comparison with the comparative example. FIG. 12 shows a diagram for explaining a potential within the photoelectric conversion element region APD of an image sensor device according to the comparative example. The photoelectric conversion element region APD according to the comparative example is the same as the photoelectric conversion element region APD according to the first embodiment, except that the photoelectric conversion element region APD according to the comparative example has no high-potential region based on the potential barrier 34.

Next, a location where electrons are generated in the photoelectric conversion element region APD will be described. In the photoelectric conversion element region APD, when a light beam enters the electron accumulation portion via a microlens, ionization occurs in the electron accumulation portion, so that electrons are generated in the electron accumulation portion. In the photoelectric conversion element region APD, the electrons generated in the electron accumulation portion are collected into the photodiodes, thereby outputting electric charges according to the amount of incident light.

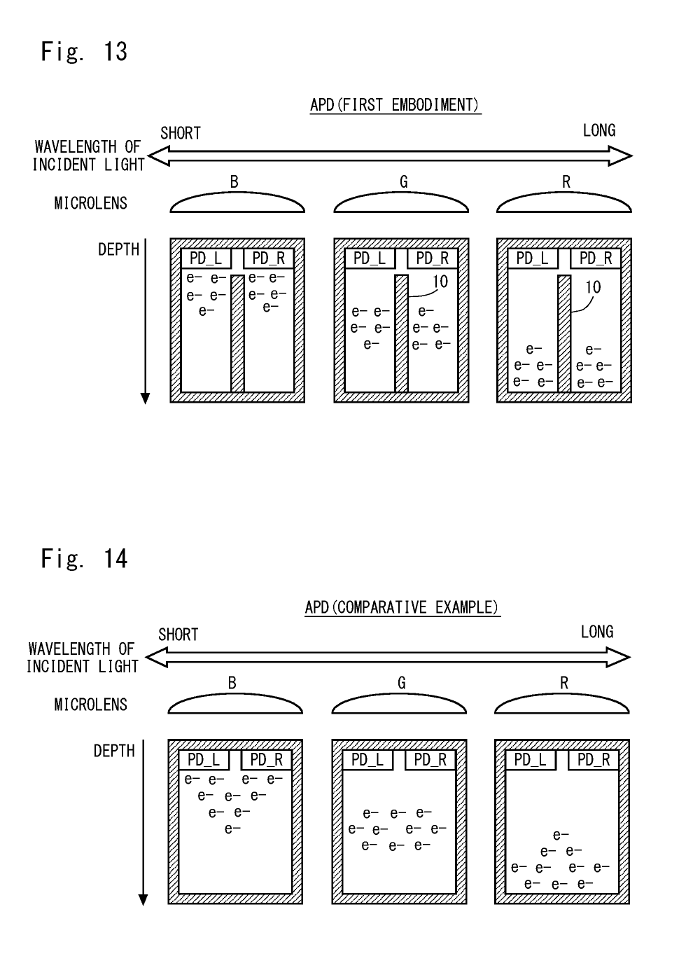

FIG. 13 shows a diagram for explaining a difference in the location where electrons are generated due to a difference between incident light wavelengths in the photoelectric conversion element region of the image sensor device according to the first embodiment. FIG. 14 shows a diagram for explaining a difference in the location where electrons are generated due to a difference between incident light wavelengths in the photoelectric conversion element region of the image sensor device according to the comparative example. Referring to FIGS. 13 and 14, in both of the examples, as the wavelength of incident light decreases, electrons are generated in a portion closer to the photodiodes (i.e., in a shallower portion of the semiconductor substrate or the electron accumulation portion), and as the wavelength of the incident light increases, electrons are generated in a portion farther from the photodiodes (i.e., in a deeper portion of the semiconductor substrate or the electron accumulation portion).

In the photoelectric conversion element region APD, the electrons generated at the locations described above are collected into the photodiodes by a slope of the potential within the electron accumulation portion. At this time, when the potential barrier 34 is present, the potential barrier 34 prevents transfer of the electrons generated below the photodiode PD_L and the electrons generated below the photodiode PD_R between the respective regions. In other words, the electron crosstalk does not occur in the photoelectric conversion element region APD according to the first embodiment. On the other hand, in the photoelectric conversion element region APD according to the comparative example which does not include the potential barrier 34, the electron crosstalk occurs in which the electrons generated below the photodiode PD_L flow to the photodiode PD_R and the electrons generated below the photodiode PD_R flow to the photodiode PD_L.

In particular, in the auto-focus operation according to the first embodiment, the electric charges are read out from the two photodiodes at the same time, so that the effect of the electron crosstalk becomes noticeable. Further, it is considered that the electric charges that cause the electron crosstalk are more likely to be generated in the region between two photodiodes.

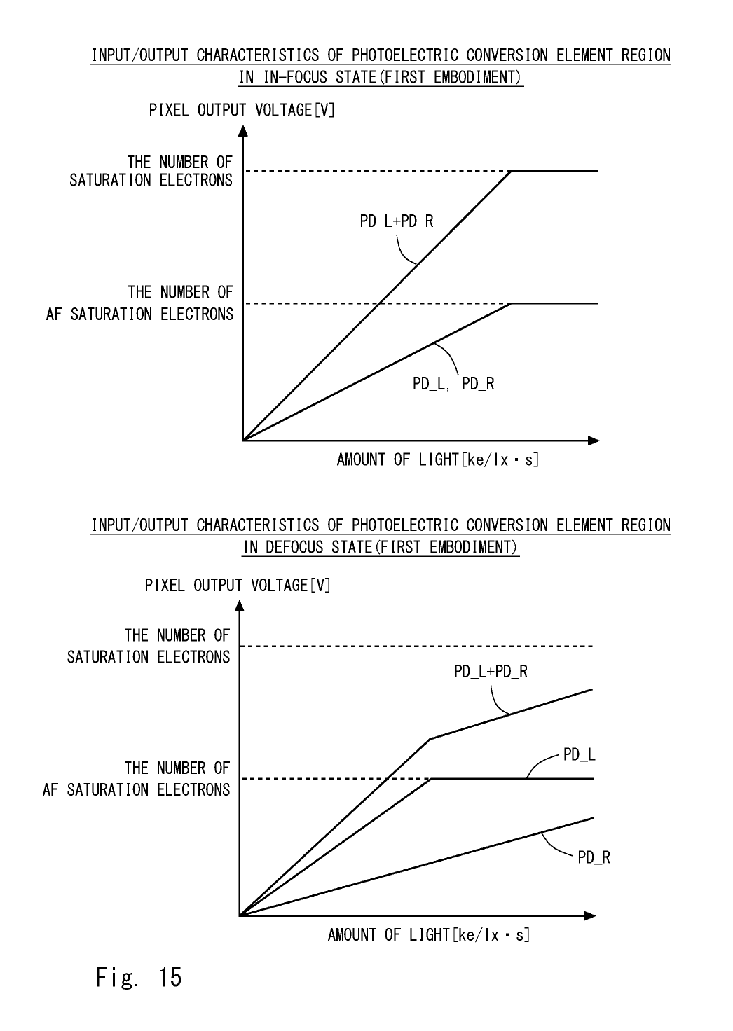

Next, input/output characteristics of the photoelectric conversion element region APD will be described. FIG. 15 shows graphs for explaining the input/output characteristics of the photoelectric conversion element region of the image sensor device according to the first embodiment. The upper graph of FIG. 15 shows the input/output characteristics of the photoelectric conversion element region APD in the in-focus state. As shown in the upper graph of FIG. 15, in the in-focus state, light is evenly incident on two photodiodes, and thus there is no difference between the outputs from the two photodiodes.

The lower graph of FIG. 15 shows the input/output characteristics of the photoelectric conversion element region APD in the defocus state. As shown in the lower graph of FIG. 15, when defocus occurs, there is a difference between the outputs from the two photodiodes with respect to the amount of incident light. The example shown in FIG. 15 illustrates a state in which the amount of light incident on the photodiode PD_L increases with respect to the amount of light incident on the photoelectric conversion element region APD due to the defocus. In this case, the photodiode PD_L is saturated with the amount of incident light (the amount of light incident on the photoelectric conversion element region APD) which is smaller than that in the in-focus state. On the other hand, in the example shown in FIG. 15, the amount of light incident on the photodiode PD_R decreases with respect to the amount of light incident on the photoelectric conversion element region APD due to the defocus. Accordingly, the photodiode PD_L is not saturated until the amount of incident light (the amount of light incident on the photoelectric conversion element region APD) which is larger than that in the in-focus state is reached.

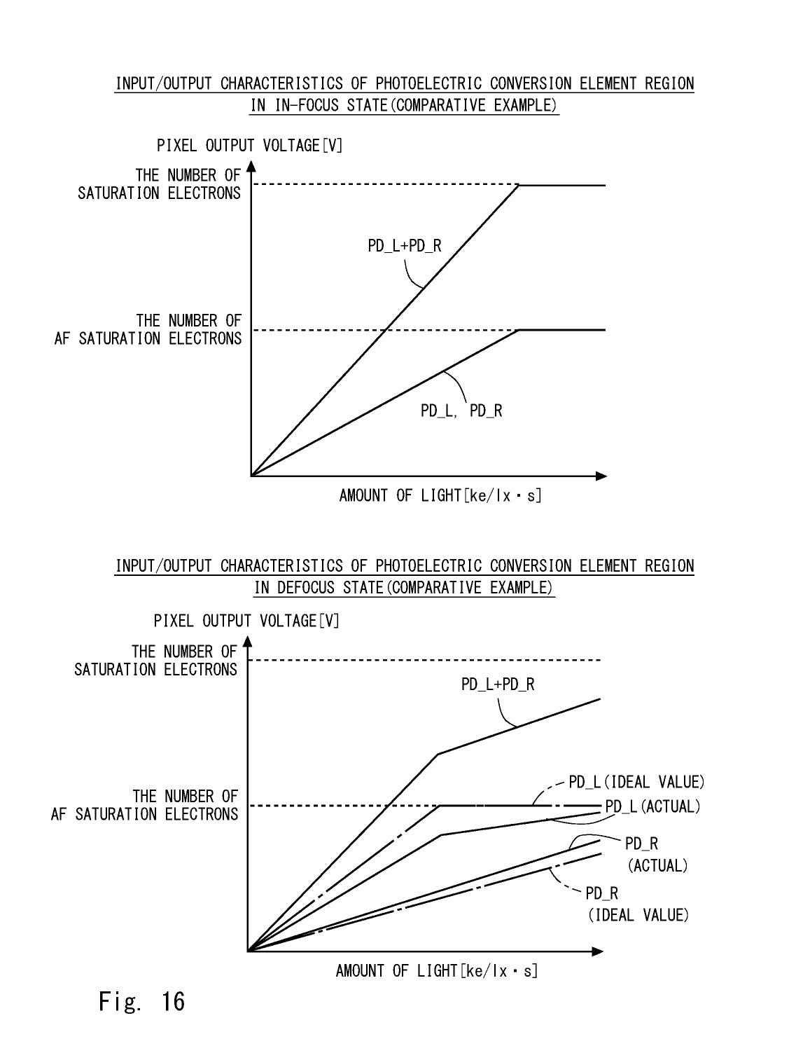

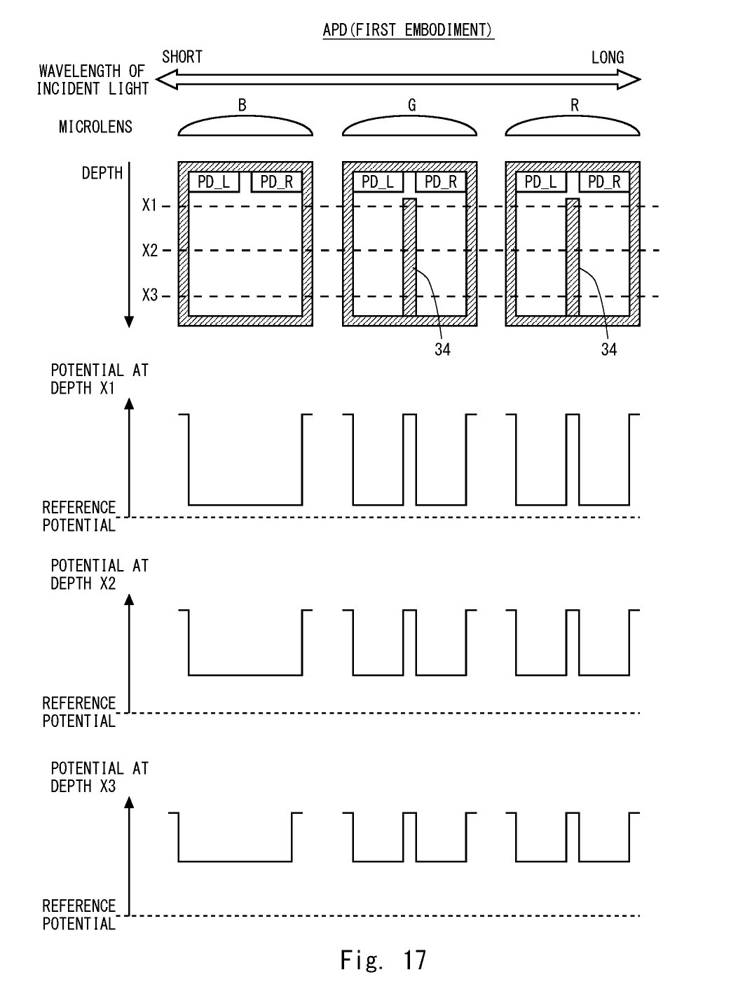

FIG. 16 shows graphs for explaining input/output characteristics of the photoelectric conversion element region of the image sensor device according to the comparative example. The upper graph of FIG. 16 shows the input/output characteristics of the photoelectric conversion element region APD in the in-focus state. As shown in the upper graph of FIG. 16, the input/output characteristics of the photoelectric conversion element region APD according to the comparative example in the in-focus state are the same as those of the photoelectric conversion element region ADP according to the first embodiment. However, since the potential barrier 34 is not provided in the photoelectric conversion element region APD according to the comparative example, the number of saturation electrons that represents the upper limit of the number of electrons which can be accumulated in the electron accumulation portion and the number of AF saturation electrons in the photoelectric conversion element region APD according to the comparative example are greater than those of the photoelectric conversion element region APD according to the first embodiment.

The lower graph of FIG. 16 shows the input/output characteristics of the photoelectric conversion element region APD according to the comparative example in the defocus state. As shown in the lower graph of FIG. 16, when defocus occurs, there is a difference between the outputs from the two photodiodes with respect to the amount of incident light. At this time, in the photoelectric conversion element region APD according to the comparative example, there is a difference between ideal input/output characteristics of the photodiodes and actual input/output characteristics of the photodiodes. Specifically, the actual input/output characteristics of the photodiode PD_L, which is saturated rapidly, are smoother than the ideal input/output characteristics thereof. On the other hand, the actual input/output characteristics of the photodiode PD_R, which is saturated slowly, are sharper than ideal input/output characteristics thereof.

Such a difference in the input/output characteristics is caused due to the electron crosstalk, which leads to deterioration in the accuracy of the auto-focus control.

As described above, the sensor 15 according to the first embodiment includes the potential barrier 34 that prevents the occurrence of crosstalk of electrons between two photodiodes in the photoelectric conversion element region APD. With this configuration, the sensor 15 according to the first embodiment can increase the accuracy of the auto-focus control without the influence of the electron crosstalk.

Further, in the sensor 15 according to the first embodiment, the electron accumulation portion formed below the photodiodes is surrounded by the N-sub layer 31 and the potential wall 33. With this configuration, the sensor 15 according to the first embodiment can reduce the electron crosstalk between the adjacent pixels.

Furthermore, in the sensor 15 according to the first embodiment, the potential barrier 34 is formed in such a manner that the potential barrier 34 extends in the depth direction from the bottom of the electron accumulation portion to the vicinity of the photodiodes, thereby preventing the occurrence of electron crosstalk also in a long migration path for electrons.

### Second Embodiment

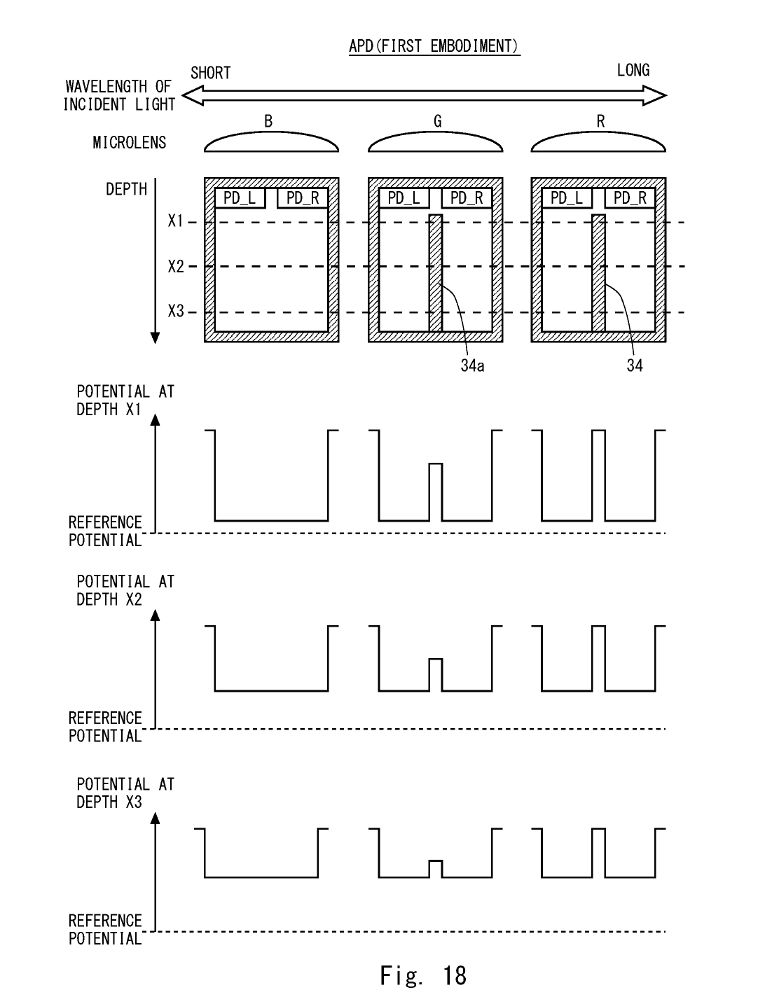

In a second embodiment, another form of the potential within the photoelectric conversion element region APD according to the first embodiment will be described. FIG. 17 shows a diagram for explaining a potential within a photoelectric conversion element region of an image sensor device according to the second embodiment.

As shown in FIG. 17, in the photoelectric conversion element region APD according to the second embodiment, the photoelectric conversion element region APD corresponding to the blue light (B) does not include the potential barrier 34. Accordingly, in the photoelectric conversion element region APD corresponding to the blue light (B), there is no high-potential region corresponding to the potential barrier 34.

In the photoelectric conversion element region APD on which the blue light (B) is incident, the volume of the electron accumulation portion in which electrons are generated tends to decrease. Accordingly, when the potential barrier 34 is provided, the volume of the electron accumulation portion further decreases due to the presence of the potential barrier 34. On the other hand, in the photoelectric conversion element region APD on which the blue light (B) is incident, electrons are generated in a portion closer to the photodiodes PD_L and PD_R and the migration length of the electrons is short, so that the electron crosstalk is less likely to occur. Thus, the potential barrier 34 is not formed only in the photoelectric conversion element region APD on which the blue light (B) is incident, thereby achieving an improvement in the number of saturation electrons and a reduction in the influence of the electron crosstalk. Moreover, a reduction in noise and an increase in image quality can be achieved by increasing the number of saturation electrons.

### Third Embodiment

In a third embodiment, another form of the setting of the potential of the photoelectric conversion element region APD according to the first embodiment will be described. FIG. 18 is a diagram for explaining a potential within a photoelectric conversion element region of an image sensor device according to the third embodiment.

As shown in FIG. 18, in the photoelectric conversion element region APD according to the third embodiment, the potential of the potential barrier 34 is set to be higher in a pixel (for example, the photoelectric conversion element region APD) that receives light with a longer wavelength. More specifically, the photoelectric conversion element region APD corresponding to the blue light (B) does not include the potential barrier 34. The potential of a potential barrier 34a of the potential barrier 34 in the photoelectric conversion element region APD corresponding to the green light (G) is set to be lower than the potential of the potential barrier 34 in the photoelectric conversion element region APD corresponding to the red light (R).

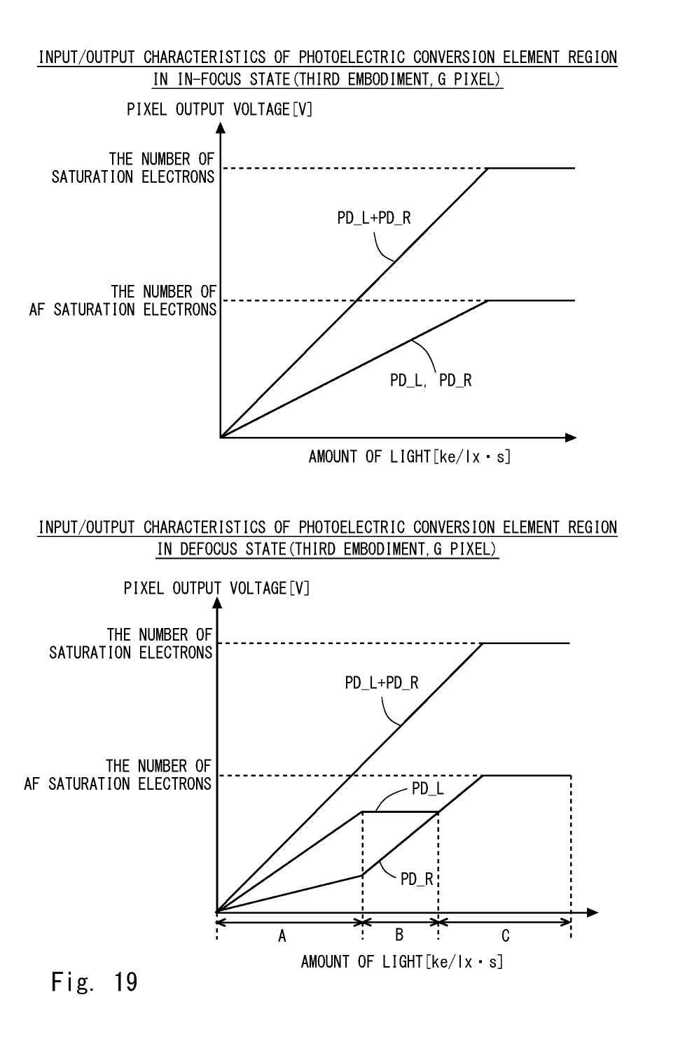

Since the potential barrier 34a having an intermediate potential is provided, the input/output characteristics of the photoelectric conversion element region APD corresponding to the green light (G) are different from those of the photoelectric conversion element region APD according to the first embodiment. FIG. 19 shows the input/output characteristics of the photoelectric conversion element region APD (for example, the photoelectric conversion element region APD corresponding to the green light (G)) of the image sensor device according to the third embodiment.

As shown in FIG. 19, in the in-focus state, the input/output characteristics of the photoelectric conversion element region APD corresponding to the green light (G) are the same as those of the photoelectric conversion element region APD according to the first embodiment. On the other hand, in the defocus state, the input/output characteristics of the photoelectric conversion element region APD corresponding to the green light (G) are different from those of the photoelectric conversion element region APD according to the first embodiment.

Specifically, in a region A in which the amount of incident light is small, the input/output characteristics of the photoelectric conversion element region APD corresponding to the green light (G) are the same as those of other embodiments. On the other hand, in a region B in which the amount of incident light is larger than that in the region A, electrons flow from one of the photodiodes (for example, the photodiode PD_L) to the other one of the photodiodes (for example, the photodiode PD_R). Accordingly, the output voltage of the photodiode PD_L in the region B becomes constant and the slope of the increase of the output voltage of the photodiode PD_R in the region B is steeper than that in the region A. In a region C in which the amount of incident light is greater than that in the region B, electrons are accumulated in the region on the opposite side of the potential barrier 34a. Accordingly, in the region C, the slopes of the increase of the output voltages of the two photodiodes are the same.

Electrons are generated in an intermediate portion of the electron accumulation portion in the photoelectric conversion element region APD corresponding to the green light (G). Accordingly, the electron migration length in photoelectric conversion element region APD corresponding to the green light (G) is shorter than that in the photoelectric conversion element region APD corresponding to the red light (R). Therefore, an increase in the amount of accumulated electric charges and a reduction in electron crosstalk can be achieved in the photoelectric conversion element region APD corresponding to the green light (G) by providing a mobility barrier only for electrons accumulated in a region having a potential equal to or lower than the potential of the potential barrier 34a.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

The first to third embodiments can be combined as desirable by one of ordinary skill in the art.

What is claimed is:

1. An image sensor device comprising a pixel region in which a plurality of pixels are arranged in a matrix,
wherein at least some of the plurality of pixels each include:
a first photoelectric conversion element and a second photoelectric conversion element that are formed on a semiconductor substrate, the first photoelectric conversion element and the second photoelectric conversion element being formed below one microlens; and
a potential barrier that inhibits transfer of electric charges between at least a part of a lower region of the first photoelectric conversion element and at least a part of a lower region of the second photoelectric conversion element in a depth direction of the semiconductor substrate.

2. The image sensor device according to claim 1, wherein the microlenses that are arranged in pixels adjacent to each other in a vertical direction and a horizontal direction among the plurality of pixels include color filters that select and transmit light beams of different colors.

3. The image sensor device according to claim 2, wherein in the plurality of pixels, pixels other than a pixel corresponding to the microlens provided with the color filter that transmits blue light include the potential barrier.

4. The image sensor device according to claim 2, wherein the potential barrier is formed to have a higher potential in a pixel that receives light with a longer wavelength.

5. The image sensor device according to claim 2, wherein the potential barrier is formed to extend from a bottom of an electron accumulation portion in a direction in which a depth of the electron accumulation portion decreases, the electron accumulation portion being formed below the first photoelectric conversion element and the second photoelectric conversion element.

6. The image sensor device according to claim 1, wherein a potential of an electron accumulation portion gradually increases in a direction approaching a bottom of the electron accumulation portion from the first photoelectric conversion element and the second photoelectric conversion element, the electron accumulation portion being formed below the first photoelectric conversion element and the second photoelectric conversion element.

7. The image sensor device according to claim 1, wherein an electron accumulation portion formed below the first photoelectric conversion element and the second photoelectric conversion element is surrounded by a potential wall having a potential higher than the potential of the electron accumulation portion.

8. An image sensor device comprising:
a first photoelectric conversion element and a second photoelectric conversion element that are formed on a semiconductor substrate below one microlens; and
a potential barrier that inhibits transfer of electric charges between at least a part of a lower region of the first photoelectric conversion element and at least a part of a lower region of the second photoelectric conversion element in a depth direction of the semiconductor substrate.

9. The image sensor device according to claim 8, wherein a potential of an electron accumulation portion gradually increases in a direction approaching a bottom of the electron accumulation portion from the first photoelectric conversion element and the second photoelectric conversion element, the electron accumulation portion being formed below the first photoelectric conversion element and the second photoelectric conversion element.

10. The image sensor device according to claim 8, wherein an electron accumulation portion formed below the first photoelectric conversion element and the second photoelectric conversion element is surrounded by a potential wall having a potential higher than the potential of the electron accumulation portion.
